(19) United States
(12) Patent Application Publication
(10) Pub. No.: US 2009/0086920 A1
(43) Pub. Date: Apr. 2, 2009

(54) X-ray Target Manufactured Using Electroforming Process

(76) Inventors: David S.K. Lee, Salt Lake City, UT (US); John E. Postman, Draper, UT (US); Dennis Runnoe, Salt Lake City, UT (US)

Correspondence Address: WORKMAN NYDEGGER/Varian;1000 Eagle Gate Tower, 60 East South Temple, Salt Lake City, UT, 84111, US

(21) Appl. No.: 11/865,068

(22) Filed: Sep. 30, 2007

(51) Int. Cl. H01J 35/10; C23C 14/14; C23C 14/22; H01J 35/08

(52) U.S. Cl. 378/144; 204/192.17; 378/143

(57) ABSTRACT

One or more components of an x-ray target assembly are manufactured using an electroforming process. The electroforming is carried out by providing an electroforming apparatus that includes an electrolyte, a metal anode, and an electrically conductive cathode. The cathode includes an intermediate x-ray target assembly upon which the metal is to be deposited and/or an electrically conductive mold for forming a component of an x-ray target assembly. The x-ray target component (e.g., a substrate or focal track) is formed by submersing the cathode in the electrolyte and applying a voltage across the anode and the cathode to cause the metal from the anode to be electroformed on the intermediate target and/or the mold. The electroforming is continued until a desired thickness of metal is achieved. The electroforming process can be used to manufacture an x-ray target substrate, focal track, stem, barrier, or other metal layer of the target assembly.

### BACKGROUND OF THE INVENTION

1. Field of the Invention

The present invention relates generally to x-ray systems, devices, and related components. More particularly, embodiments of the invention relate to x-ray target assemblies that are manufactured using an electroforming process.

2. Related Technology

The x-ray tube has become essential in medical diagnostic imaging, medical therapy, and various medical testing and material analysis industries. An x-ray tube typically includes a cathode assembly and an anode assembly disposed within an evacuated enclosure. The cathode assembly includes an electron source and the anode assembly includes a target surface that is oriented to receive electrons emitted by the electron source. During operation of the x-ray tube, an electric current is applied to the electron source, which causes electrons to be produced by thermionic emission. The electrons are then accelerated toward the target surface of the anode assembly by applying a high-voltage potential between the cathode assembly and the anode assembly. When the electrons strike the anode assembly target surface, the kinetic energy of the electrons causes the production of x-rays. Some of the x-rays so produced ultimately exit the x-ray tube through a window in the x-ray tube, and interact with a material sample, patient, or other object.

Stationary anode x-ray tubes employ a stationary anode assembly that maintains the anode target surface stationary with respect to the stream of electrons produced by the cathode assembly electron source. In contrast, rotating anode x-ray tubes employ a rotating anode assembly that rotates portions of the anode's target surface into and out of the stream of electrons produced by the cathode assembly electron source. The target surfaces of both stationary and rotary anode x-ray tubes are generally angled, or otherwise oriented, so as to maximize the amount of x-rays produced at the target surface that can exit the x-ray tube via a window in the x-ray tube.

In an x-ray tube device with a rotatable anode, the target has previously consisted of a disk made of a refractory metal such as tungsten, and the x-rays are generated by making the electron beam collide with this target, while the target is being rotated at high speed. Rotation of the target is achieved by driving the rotor provided on a support shaft extending from the target. Such an arrangement is typical of rotating x-ray tubes and has remained relatively unchanged in concept of operation since its induction.

Because of the high melting point of the metals used to make x-ray targets, most x-ray targets are made using powder metallurgy. In powder metallurgy, the metal part is manufactured by pressing a powder and then sintering the powder to form the part. The part is then heated and forged to cause densification. In many cases, the powder is densified up to 97% a theoretical density.

### BRIEF SUMMARY OF THE INVENTION

Embodiments of the invention concern x-ray target assemblies that are manufactured using an electroforming process. The electroforming process can be used to manufacture various components of the anode assembly, including but not limited to, an x-ray target substrate, an x-ray target focal track, an x-ray target stem, a metal barrier layer on a metal x-ray target substrate, a metal barrier layer on a carbon x-ray target substrate, a metal barrier layer on a carbon x-ray target heat sink, or a metal layer that mechanically couples two or more additional components of the x-ray target assembly. The electroforming process can be used to manufacture x-ray targets with a unique design and/or improved material properties.

The electroforming process used to manufacture the one or more components of the x-ray target can by carried out by providing an electroforming apparatus that includes an electrolyte, a metal anode, and an electrically conductive cathode. The electrically conductive cathode includes (i) an intermediate x-ray target assembly upon which the metal is to be deposited and/or (ii) an electrically conductive mold for forming a component of an x-ray target assembly.

The x-ray target component (e.g., a substrate or focal track) is formed by submersing the cathode in the electrolyte and applying a voltage across the anode and the cathode to cause the metal from the anode to be electrodeposited on the intermediate x-ray target and/or the cathode mold. The electrodeposition is continued until a desired thickness of metal is formed.

The electroforming process of the invention can be used to deposit high melting point metals typically used in manufacturing high performance x-ray target assemblies. Examples of high melting point metals that can be used to manufacture components of an x-ray target assembly include, but are not limited to Mo, Ta, Re, W, Nb, V, Ir, Rh, Pt, and Pd.

The electrodeposition of high melting point metals is facilitated by the use of a molten salt electrolyte and high operating temperatures. Examples of suitable temperatures for carrying out electrodeposition of high melting point metals includes temperatures greater than about 500° C., more preferably greater than about 800° C., and up to 1000° C. Examples of suitable molten salts that can be used as electrolytes include, but are not limited to, sodium chloride, potassium chloride, sodium fluoride, potassium fluoride, and the like.

The electroformed component is then incorporated into an x-ray target assembly. The x-ray target assemblies of the invention typically include a substrate and a target surface such as a focal track. The target assembly can also include a x-ray target stem and/or barrier layers that separate two or more components of the x-ray target assembly. The barrier layer can be used to separate a carbon based substrate from the focal track material or from the heat sink. The barrier layer can also be used to provide a thermal barrier between a carbon heat sink and the x-ray target stem by reducing radiative heat.

The electroformed component can also be a metal layer that connects two or more other components of the x-ray target assembly together. For example, an x-ray target stem that is attached to the substrate using a fastener can be secured by applying a coating over the fastener and the substrate using the electrodeposition technique of the invention. The electroformed coating can be used in place of or in addition to braze washers that are typically used for this purpose.

The use of electroforming to manufacture one or more components of the x-ray target assembly has surprising and unexpected results in the performance of the x-ray target. Components manufactured using electrodeposition have superior microcrystalline properties compared to components made by powder metallurgy. The electrodeposited components have substantially 100% density. The high density results in very low porosity. The high density and low porosity is advantageous for a track material due to its ability to emit x-rays upon impingement of electrons. In addition, high density leads to increased strength, which allows the target assembly to be operated under more strenuous and thus higher performance conditions (e.g., greater than 650° C.).

Another significant advantage of the components manufactured using the electroforming process is the columnar microcrystalline structure that the process produces. FIG. 14 is a photograph showing the columnar microcrystalline structure. The crystal grain of the electroformed components is very fine and aligned in the vertical or columnar direction. By aligning the grain vertically with respect to the target, the materials strength and ductility is improved compared to components made using powder metallurgy. Surprisingly it has been found that a tungsten track can be formed without the need to add rhenium to achieve satisfactory ductility due to the improved ductility provided by the columnar microcrystalline structure. The columnar microcrystalline structure provides advantages for any component manufactured using the electroforming process due to the high density and increased strength.

Another advantage of the targets manufactured according to the present invention is the thickness with which the highly ordered crystal lattice can be grown. The columnar microcrystalline structure can be grown to thicknesses of greater than 0.75 mm, more preferably greater than 1 mm, and most preferably greater than about 1.25 mm. Metal layers grown at these thicknesses can provide excellent bonding between layers and can provide a rigidity that avoids the situation where the metal layer delaminates and curls up. These results are in contrast to targets made using a CVD process, which are often limited to deposition depths of less than about 0.5 mm due to extremely slow deposition rates (often more than 20 times slower than the electroforming process of the present invention). The high deposition rates used in the present invention allow for greater thicknesses and give the deposited material a highly dense, highly ductile, and unique microcrystalline structure.

Surprisingly, targets manufactured using the process of the present invention have achieved high power rating during operation in an x-ray tube. The targets of the present invention can be used at track power rating of from about 60 kW to about 150 kW, more preferably 80 kW to about 125 kW, depending on target size (e.g., target with 200 mm diameter). These higher power ratings allow higher performance when used in an x-ray tube.

These and other advantages and features of the invention will become more fully apparent from the following description and appended claims.

### BRIEF DESCRIPTION OF THE DRAWINGS

In order that the manner in which the above-recited and other advantages and features of the invention are obtained, a more particular description of the invention briefly described above will be rendered by reference to specific embodiments thereof which are illustrated in the appended drawings. Understanding that these drawings depict only typical embodiments of the invention and are not therefore to be considered limiting of its scope, the invention will be described and explained with additional specificity and detail through the use of the accompanying drawings in which:

FIG. 1A is a cross-sectional view of an x-ray target assembly according to one embodiment of the invention;

FIG. 1B is an end view of the x-ray target assembly of FIG. 1A showing the disk-like shape of the substrate and track;

FIG. 2 is a cross-sectional view of an x-ray target assembly according to another embodiment of the invention;

FIG. 3 is a schematic drawing of an electroforming apparatus including an electrolyte, anode, and cathode;

FIG. 4A is a cross-sectional view of an x-ray target substrate coated on a block of carbon according to one embodiment of the invention;

FIG. 4B is a cross-sectional view of the x-ray target substrate of FIG. 4A machined to further shape the intermediate target assembly;

FIG. 5A is a cross-sectional view of an x-ray target substrate with a layer of a focal track material coated on the substrate according to one embodiment of the invention;

FIG. 5B is a cross-section view of the x-ray target substrate and focal track of FIG. 5A after machining the x-ray target substrate and focal track to have a desired shape;

FIG. 6A is a cross sectional view of a portion of an x-ray target assembly manufactured according to the present invention using carbon as a substrate;

FIG. 6B is a cross-sectional view of a portion of the x-ray target assembly of FIG. 6A further including a barrier layer;

FIG. 6C is a cross-sectional view of a portion of the x-ray target assembly of FIG. 6B with a portion of the barrier layer and a metal layer removed;

FIG. 7A is a cross-sectional view of a portion of an x-ray target assembly having a stem manufactured according to one embodiment of the invention;

FIG. 7B is a cross-sectional view of the substrate of the target assembly of FIG. 7A coated prior to forming the stem;

FIG. 8 is a cross-sectional view of a portion of an x-ray target assembly according to one embodiment of the invention showing various components of an x-ray target assembly coupled together using an electroformed layer of metal;

FIG. 9 is a cross-sectional view of an intermediate x-ray target assembly manufactured according to one embodiment of the invention;

FIG. 10 is a cross-sectional view of an intermediate x-ray target assembly masked with a non-conductive material and plated with a focal track material according to one embodiment of the invention;

FIG. 11 is a cross-sectional view illustrating a plurality of targets manufactured in part during the same electroforming process;

FIG. 12 is a cross sectional view of a multi-target assembly manufactured according to one embodiment of the invention;

FIG. 13 illustrates the use of the x-ray target assembly of the invention in an x-ray tube; and

FIG. 14 is a photograph of a cross-section of a metal layer of an x-ray target manufactured using an electroforming process according to the present invention.

### DETAILED DESCRIPTION OF EMBODIMENTS OF THE INVENTION

### 1. Introduction

The present invention relates to the manufacture of x-ray target assemblies (i.e, the x-ray target anode) by electroforming one or more metal layers of the target. The present invention can be carried out on any type of x-ray target that includes metal layers made from high melting point metals, such as, but not limited to, refractory metals.

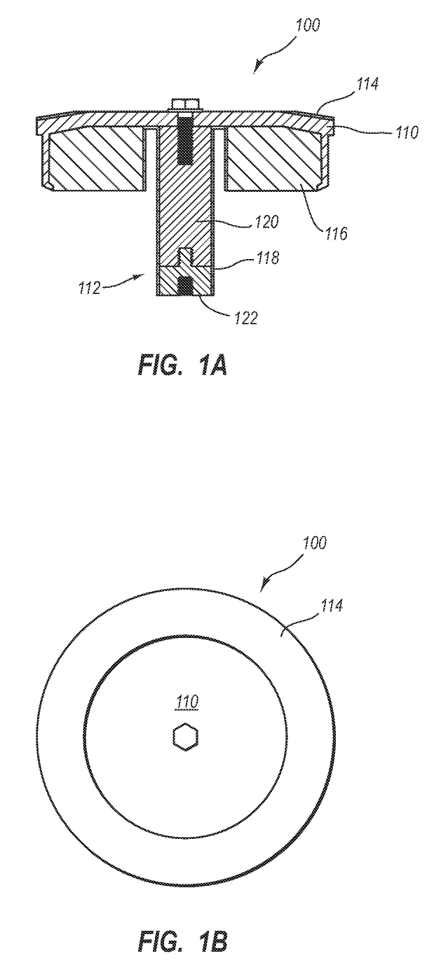

FIGS. 1A and 1B depict various features of an x-ray target assembly according to the one embodiment of the invention. Reference is first made to FIG. 1A, which illustrates in cross-section a simplified structure of an example rotating-type x-ray target assembly 100. The x-ray target assembly 100 includes a target substrate 110. A stem 112 is integrally formed with the target substrate 110. Stem 112 includes a graphite stem core 120 and a bearing stud 122. A target focal track 114 is formed on the upper surface of the target substrate using an x-ray emitting material such as, but not limited to, tungsten or tungsten-rhenium. Electrons generated by a cathode (not shown) impinge on the focal track 114. The x-ray emitting metal of focal track 114 emits x-rays in response to the impingement of electrons. In this example, target substrate 110 is backed by a heat sink 116. Heat produced from the impingement of the electrons is mostly dissipated through heat sink 116. FIG. 1B is a top view of target assembly 100. The target substrate 110 and focal track 114 can be shaped like a disk to facilitate high speed rotation. However, if desired, other shapes can be used.

The anode assembly 100 is rotated by an induction motor, which drives stem 112.

In a typical x-ray tube, the anode and cathode assemblies are sealed in a vacuum envelope. The stator portion of the motor is typically provided outside the vacuum envelope. The x-ray tube can is enclosed in a casing having a window for the X-rays that are generated to escape the tube. The casing can be filled with oil to absorb heat produced as a result of x-ray generation.

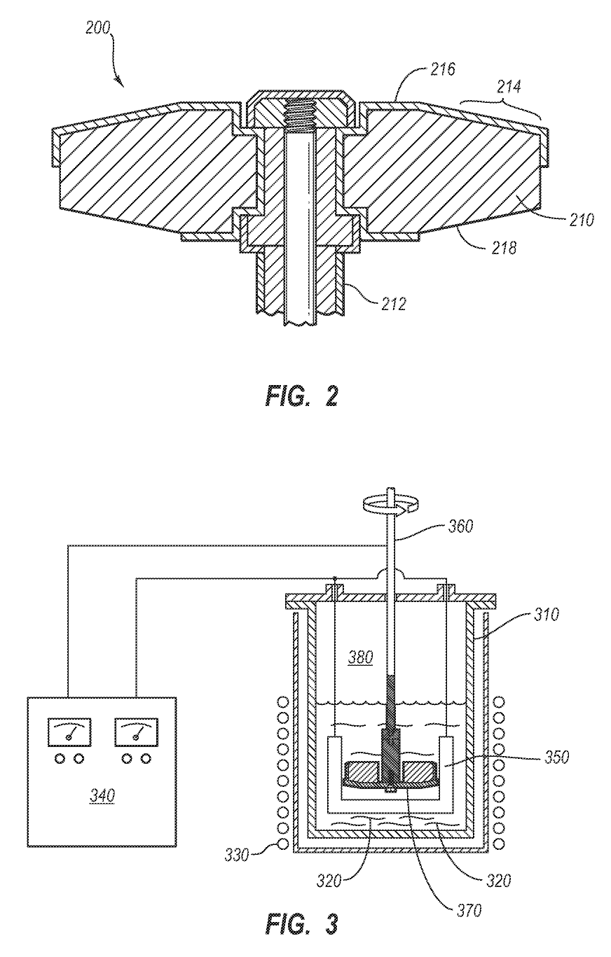

The x-ray target illustrated in FIGS. 1A and 1B show the track supported by a metal substrate layer. In an alternative embodiment, the structural support for the track can be provided by a carbon-based substrate. FIG. 2 illustrates a target 200 that includes a carbon based substrate 210 and a target stem 212 connected to substrate 210. The carbon based substrate serves as a heat sink and as the structural support for focal track 214. Focal track 214 can be formed directly on carbon substrate 210 using an electrodeposition process to form metal layer 216. Metal layer 216 can extend around a substantial portion of substrate 210 to provide strength. Layer 216 can terminate to leave a portion 218 of substrate 210 exposed to facilitate heat transfer during use.

While FIGS. 1A, 1B, and 2 illustrate two example x-ray targets according to the present invention, the present invention includes other x-ray target designs that include one or more metal layers.

The following provides a description of x-ray targets manufactured using an electroforming process. As described in more detail below, the electroforming process can advantageously be used to manufacture various metal components of the x-ray target assembly, including but not limited to the substrate, the focal track, the stem, barrier layers, and other metal layers used to strengthen and/or secure the components of the x-ray target assembly. X-ray target assemblies manufactured, at least in part, using the electroforming process have improved mechanical properties compared to target assemblies manufactured using powder metallurgy techniques. These improved properties are due to the unique microcrystalline structure of the metal layers deposited using electroforming. In addition, by electroforming the one or more metal components of the x-ray target, the target can be manufactured in unique steps that improve the target design and/or reduce the cost of manufacturing the x-ray target.

For purposes of this invention, the term “x-ray target assembly” or “assembly” includes x-ray target components (e.g., a substrate, a stem, or a carbon heat sink) that are “assembled” by both mechanical means (e.g., a fastener) and/or metallurgically (e.g., brazed or electrodeposited).

### II. Electroforming Process

The electroforming process used to manufacture one or more metal components of the x-ray target is carried out by electrodepositing a metal using an electroforming apparatus. FIG. 3 is a schematic drawing of an electroforming apparatus 300. The electroforming apparatus includes a vessel 310 that holds a liquid electrolyte 320 and an inert atmosphere 380. Vessel 10 can be a graphite material or other material inert to salt at high temperatures. Inert atmosphere can be provided by any inert gas such as nitrogen or argon. A heating element 330 surrounds the vessel 310 and allows the electrolyte to be heated to a desired temperature. Power supply 340 is connected to a positively charged anode 350 and a negatively charged cathode 360. The electroforming anode 350 includes the metal that is to be consumed during electrodeposition. The metal of anode 350 is submerged in electrolyte 320. The cathode 360 is submerged in the electrolyte and spaced apart from the anode. The cathode 360 provides the surface where the metal from the anode is deposited. In FIG. 3, the portion of the cathode 360 submerged in electrolyte is an intermediate 370 of x-ray target 100. Applying a voltage across anode 350 and cathode 360 causes metal to be dissolved in the electrolyte and deposited on the electrically conductive surfaces of intermediate 370 of x-ray target 100. Examples of electroforming apparatuses suitable for use with the present invention are devices used with the EL-Form™ process (Plasma Processes, Inc.).

The metals deposited using the electroforming process of the invention can be any metal suitable for use in manufacturing high performance x-ray targets. The metals used to manufacture high performance x-ray target are typically high melting-point metals having a melting point above about 1650° C. Examples include Mo, Ta, Re, W, Nb, V, Ir, and Rh. More preferably, the metal is a refractory metal selected from the group of tungsten, molybdenum, niobium, tantalum, and rhenium.

The metals used for electroforming can be provided in relatively pure form or alternatively they can be scrap metals which various amounts of contaminants. In several embodiments of the invention impure metals can be used as the anode metal since the electrodeposition process selectively deposits only the pure metal. Thus, the electrodeposition process of the invention can use cheaper, impure sources of metal while achieving very high purity electroformed components.

The electrodeposition is carried out until a desired thickness is reached. The time needed to reach a particular thickness depends on the rate of deposition. In one embodiment the deposition rate is in a range from about 5 micron/h to about 80 micron/h, more preferably in a range from about 25 micron/h to about 50 micron/hr. The thicknesses of the electroformed component is typically limited by the need for a practical duration. The rate of deposition using the electroforming process of the invention can yield thicknesses in a range from about 0.02 mm to about 5 mm, more preferably about 0.75 mm to about 5 mm, even more preferably about 1 mm to about 3.5 mm, and most preferably about 1.25 mm to about 3 mm.

In a preferred embodiment, the electroforming process is carried out at a relatively high temperature. Heating element 330 is used to control the temperature of the electrolyte 320 during deposition of the metal. Examples of suitable temperatures include temperatures greater than about 500° C., more preferably greater than about 800° C., and up to 1000° C. Electroforming performed at these temperatures reduces internal deposition stresses, which allows relatively thick layers of metal to be formed. In addition, deposition at these higher temperatures gives the metals smaller and more uniform grain sizes. In a preferred embodiment, the microcrystalline structure of the metal deposited at a high temperature is columnar.

The electrolyte used during the deposition process can be any electrolyte capable of acting as a medium to dissolve metal atoms from the anode and transfer the metal atoms to the cathode. In one embodiment, the electrolyte is a molten metal salt. Example of suitable salts include chlorides or fluorides of sodium or potassium or both. The salt can be made molten by applying heat using heating element 330 of electroforming apparatus 300.

During the metal deposition, the voltage across the anode and the cathode allows the metal atoms to be dissolved in the electrolyte and carried through the electrolyte to the cathode. The negative charge on the surface of the cathode causes the positively charged metal atoms in the electrolyte to be deposited. Electrodeposition occurs anywhere there is negatively charged surface in contact with the electrolyte.

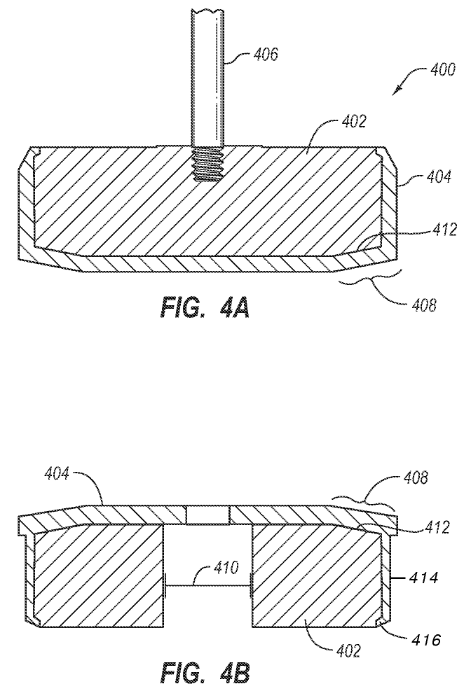

The shape of the negatively charged surface of the cathode determines the shape of the electrodeposited metal layer. The cathode can be made to have almost any desired negatively charged surface. However, to maximize uniformity in the electrodeposited layer it is advantageous to avoid sharp corners and other fine points. In one embodiment, the electrically conductive surface area is provided by an intermediate x-ray target. For example, as described in more detail below with regard to FIGS. 4-9, a carbon heat sink can be used as the cathode for depositing a substrate, a target substrate can be used for depositing an x-ray target focal track, or an x-ray target stem core coupled to a substrate can be used for depositing a stem sleeve.

Alternatively, the electrically conductive cathode surface can be a form that provides a desired shape for making an x-ray target component but is then separated from the x-ray target component. For example, the form can be a carbon block that provides a desired shape for making an x-ray target substrate. The carbon block can then be removed and the electroformed substrate can be incorporated into an x-ray target assembly. For purposes of this invention, the term “electroforming” encompasses both a process where the “mold” or “form” is separated from the deposited metal and a process where the mold or form (e.g., a target substrate) remains attached to the deposited material and therefore becomes part of the finished x-ray target.

The shape of the deposited metal layer can also be controlled by masking a portion of the surface of the cathode using a non-conductive material. For example, where an intermediate x-ray target is used as the cathode, portions of the intermediate x-ray target can be masked with a chemically inert and non-conductive material to avoid coating that portion of the intermediate target. An example of a suitable non-conductive material is a ceramic material such as boronitride or borocarbide. Where a ceramic material is used, relatively lower temperatures can be used to ensure stability of the ceramic material in the electrolyte. Following electrodeposition, the mask is removed to yield an uncoated surface (i.e., uncoated with respect to the material being deposited in that particular deposition step).

In an alternative embodiment, the mask can be a conductive material that is used as a sacrificial mask. In this case the mask can be a graphite or other material that is coated during electrodeposition but the mask can be easily removed so as to not require extensive machining of the intermediate targets.

The shape of the electroformed component is also determined in part by the thickness of the deposited metal. The thickness is controlled by allowing electrodeposition to continue until the desired thickness of metal is achieved. The thickness of the electroformed component depends on the rate of deposition and the duration of deposition. The rate of deposition can depend on the electrolyte used, the type of metal being deposited, and the voltage applied by the electroforming apparatus. The electroforming process used in the present invention can be relatively fast as compared to other techniques such as chemical vapor deposition. Unlike some deposition techniques, the electroforming process of the invention can have sufficiently high deposition rates to achieve metal thicknesses suitable for making x-ray target substrates, x-ray target focal tracks, x-ray target stems, and other useful metal components of an x-ray target assembly. In one embodiment, the rate of deposition used in the method of the invention is in a range from about 5 microns/h to about 80 micron/h, more preferably in a range from about 25 micron/h to about 50 micron/h.

In one embodiment, the electrodeposition is used to deposit a composite metal or alloy. Using two or more different metals in the electroforming anode results in a uniform deposition of both metals. If desired, the concentration of the two or more metals can be varied throughout the deposition process to yield a layer with a continuously or semi-continuously variable composition (i.e., a graded composition). A graded composition can be used to ensure that certain alloying metals are placed closer to a surface or component interface where the alloying metal is more important. alternatively a graded alloying composition can provide a transition layer between two dissimilar layers, thereby improving the bonding between two dissimilar layers and reducing the likelihood of delamination.

The electroformed x-ray target component can be formed so as to have its final desired shape, or alternatively, the electroformed component can be further machined to have the shape and dimensions desired for incorporating the component into an x-ray target assembly.

### III. Electroformed Components of an X-Ray Target

The electroforming process of the invention is used to manufacture one or more components of an x-ray target assembly. Examples of suitable components of an x-ray target assembly that can be manufactured according to the present invention include, but are not limited to, the x-ray target substrate, the x-ray target focal track, the x-ray target stem, barrier layers incorporated into the x-ray target assembly, and other metal layers used to strengthen and/or secure the components of the x-ray target assembly.

FIGS. 4A-4B illustrate a method for forming a carbon substrate according to one embodiment of the invention. FIG. 4A shows an intermediate x-ray target 400 that includes a carbon block 402 and an x-ray target substrate 404. A support member 406 is attached to carbon block 402. Support member 406 is made of an electrically conductive material such as metal that provides electrical contact to block 402. Support member 406 is used to suspend bock 402 in the electrolyte bath during electroforming and conduct a negative charge to the surface of block 402. During electroforming, support member 406 can be rotated to cause block 402 to spin. Rotating block 402 during electroforming can better ensure a uniform thickness for substrate 404.

The metal or metals electrodeposited to form substrate 404 can be any metals suitable for use as an x-ray target substrate. Examples of suitable material for forming a metal substrate include, but are not limited to, molybdenum and molybdenum alloys such as Mo—W, Mo—Re, or Mo—W—Re. The electrodeposition process can be used to form almost any desired composition so long as the composition includes materials that can be electrodeposited. If desired the substrate can be a composite material and/or a composite material with a graded composition of an alloying element. In one embodiment, the alloying element has a higher concentration at the surface where the substrate contacts another component (e.g., the focal track). For example, a substrate including Mo and W can have a higher percentage of W near the substrate track interface.

Advantageously the electroforming process of the invention can be used to form a relatively thick substrate. Examples of thicknesses that can be achieved in a relatively reasonable period are in a range from about 0.5 mm to about 5 mm.

Substrate 404 is typically formed to have an angled focal track location 408. Focal track location 408 is the location where a focal track material can be deposited for making an x-ray target focal track. Because electrodeposition tends to deposit a uniform thickness, in a preferred embodiment, block 402 has angled surface 412 that corresponds to focal track location 408. In an alternative embodiment, focal track location 408 can be made by machining target substrate 404 after it has been electroformed. The thickness of substrate 404 is determined by controlling the rate of deposition and the duration of deposition. Any focal track material can be deposited on focal track location 408 using any technique, including electroforming, CVD, or other known deposition techniques.

FIG. 4B illustrates intermediate x-ray target 400 following electroforming. In FIG. 4B, intermediate target 400 has been machined to make a central bore 410 in carbon block 402. Central bore 402 can be machined out using techniques known in the art. In this embodiment, carbon block 402 remains bonded to substrate 404 and serves as a heat sink in the x-ray target assembly. In an alternative embodiment, the entire carbon block 402 can be removed to yield an electroformed substrate 404.

To retain carbon block 402 as a heat sink, the carbon material is typically selected so as to have a similar coefficient of thermal expansion as substrate 404. Matching the coefficient of thermal expansion of substrate 404 and carbon block 402 avoids the separation that can occur when materials of substantially different coefficients are cooled following electroforming. Alternatively, if it is desired to remove carbon block 402 after electrodeposition, the coefficients of thermal expansion can be selected to be different to facilitate separation. The coefficient of thermal expansion of metals and carbons useful for forming x-ray target components are known in the art and selecting similar or dissimilar coefficients is within the skill of those in the art.

A portion of the upper surface of carbon block 402 can remain uncoated as shown in FIG. 4A. For example, an upper surface can remain uncoated by controlling the depth of carbon block 402 in the electrolyte. By avoiding the submersion of the upper surface of block 402 in the electrolyte, the coating of the surface can be avoided. Alternatively, the upper surface of block 402 can be coated and then machined to remove the coating. In yet another alternative embodiment, the surface and/or support member 406 can remain uncoated by applying a sacrificial mask that can be removed after electroforming.

The substrate 404 manufactured according to the invention is incorporated into an x-ray target assembly. In one embodiment, the x-ray target assembly is incorporated into a rotating anode target that includes an x-ray focal track, a stem, and/or a carbon heat sink. These components of the x-ray target assembly can be manufactured or provided using techniques known in the art or alternatively, where a metal is used, the component can be provided by electroforming according to the present invention and as described herein.

The intermediate target assembly 400 can be particularly advantageous for use in rotating anode targets due to the ability to form a non-planar interface between substrate 404 and heat sink 402. As shown in FIG. 4B, heat sink 402 has several non-planar surfaces that interface with substrate 404. For example, the interface between heat sink 402 and substrate 404 includes the angled portion 412, a skirt 414, and cap 416 that extends inward at the bottom of heat sink 402. Because x-ray target substrate 404 is electroformed using heat sink 402 as the form, heat sink 402 can be shaped in any way desired to provide a substrate with unique and beneficial properties.

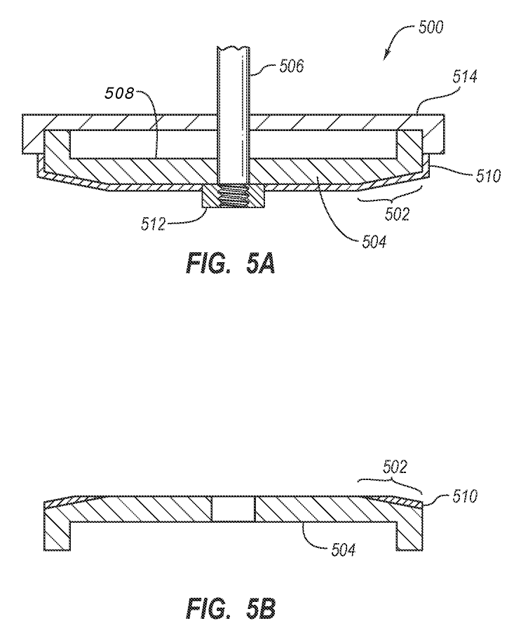

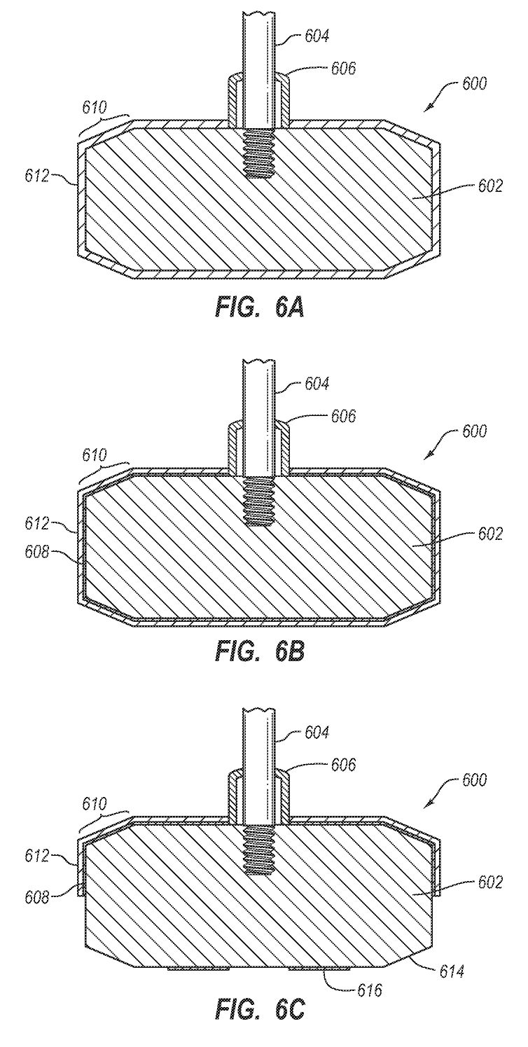

The use of the angled portion 412 of heat sink 402 forms a focal track location with a desired angle for depositing a focal track. In addition, the heat sink is evenly spaced from the focal track at the substrate-heatsink interface. This is in contrast to targets that are shaped in a way that is suitable for brazing a heat sink onto the substrate (e.g., substrate 504 shown in FIG. 5B). Substrates used in brazed targets typically have a flat interface with the heat sink to facilitate formation of the braze. In contrast, an electroformed substrate can be formed on any shape of heat sink so long as the surface of the heat sink can be properly exposed to an electrolyte during the electroforming process. For example, angled portion 412 illustrated in FIG. 4B provides an angled surface for forming focal track location 408 of substrate 404. Advantageously substrate 404 has a uniform thickness directly below the focal track location 408, without the need to increase the thickness of the entire substrate. This uniform thickness while still achieving the desired track angle is made possible by the electroforming process, which does not require a braze.

Another advantage of the electroformed substrate 404 of intermediate x-ray target 400 is the use of a skirt 414 and cap 416. One limitation of rotating anode targets is the rotation speed at which the heat sink will begin to fail. For example an 8 inch graphite target manufactured using methods known in the art can currently be rotated at about 9,000 RPM without fracturing. Skirt 414 of substrate 404 extends vertically down the lateral side of heat sink 402 and protects heat sink 402 from fracturing. Skirt 414 can extend along the entire lateral side of heat sink 402 or a portion thereof. In a preferred embodiment, skirt 414 extends along at least about 50% of the lateral edge, more preferably at least about 80% and most preferably substantially the entire lateral edge. In one embodiment, skirt 414 can include a cap 416 that extends inward from the lateral edge near an exposed bottom surface of heat sink 402. Cap 416 extends around the bottom of heat sink 402 to help prevent heat sink 402 from debonding from substrate 404.

X-ray target assemblies that have substrates employing a skirt 414 can be rotated as substantially higher rotation speeds than a similar target that does not have a skirt. In one embodiment, the x-ray target is a rotating anode target having a skirt on the lateral edge of the heat sink and the target assembly can be rotated at rates of between 9,000 and 15,000 RPM, more preferably 10,000-12,000 RPM during use (for a target greater than 8 inches in diameter). Rotating the target at higher speeds improves thermal loading on the focal track, thereby distributing the heat and allowing longer and/or higher performance targets.

FIGS. 5A and 5B illustrate an intermediate target assembly 500 with an x-ray focal track 502 formed using an electroforming process. To manufacture intermediate target assembly 500, a substrate 504 is suspended in an electrolyte using support member 506. A thin layer of focal target material 510 is deposited on substrate 504 using electroforming apparatus 300 (FIG. 3). If the focal track is grown on a metal substrate, the electrodeposition is preferably carried out so as to deposit a track with a depth of between about 1.0 mm and about 1.25 mm, although other thickness can be used if desired.

A ceramic nut 512 secures support member 506 to substrate 504 during the electroforming process. Ceramic nut 512 is made from a dielectric material such that no material is deposited on the portion of the surface of substrate 504 that is encapsulated by nut 512. A ceramic mask 514 can be used to cap the underside 508 of substrate 504 to prevent underside 508 from being coated with metal. However, if desired, mask 514 is not used and layer 510 extends onto the surface of underside 508. In such an embodiment, this portion of layer 510 can become part of the final x-ray target assembly or alternatively any undesired portion can be removed using known techniques such as grinding.

Electroformed metal layer 510 can be further processed to provide an x-ray target component with a desired shape. FIG. 5B shows metal layer 510 machined so as to leave substantially only the portion of layer 510 that forms focal track 502.

FIGS. 5A and 5B show focal track 502 manufactured on a metal substrate 504. Substrate 504 can be made from any material using any technique so long as substrate 504 is electrically conductive at the surface where focal track 502 is to be deposited. In one embodiment, substrate 504 is manufactured using an electroforming process as described above. Alternatively, substrate 504 can be manufactured using powder metallurgy or any other known technique. Examples of suitable substrate materials include carbon, TZM, Mo, and Mo alloys, among others. In one embodiment, the substrate is an oxide dispersion strengthened metal alloy (e.g., ODS Mo alloys).

In an alternative embodiment of the invention, an x-ray target focal track is electroformed on a carbon substrate. FIGS. 6A-6C illustrate example embodiments of an intermediate x-ray target assembly 600 with a focal track electroformed on a carbon substrate. Intermediate x-ray target 600 includes a carbon substrate 602, a support member 604, a collar 606, and a metal layer 612. Metal layer 612 provides an x-ray target focal track 610. Collar 606 can be a non-conductive material or a sacrificial masking.

Metal layer 612, which includes x-ray focal track 610, is formed on substrate 602 using an electroforming apparatus 300 (FIG. 3). The electrodeposition is preferably carried out so as to deposit a track with a depth of between about 1.25 mm and about 1.5 mm, although other thickness can be used if desired. Support member 604 can be used to suspend and rotate carbon substrate 602 in electrolyte 320 (FIG. 3).

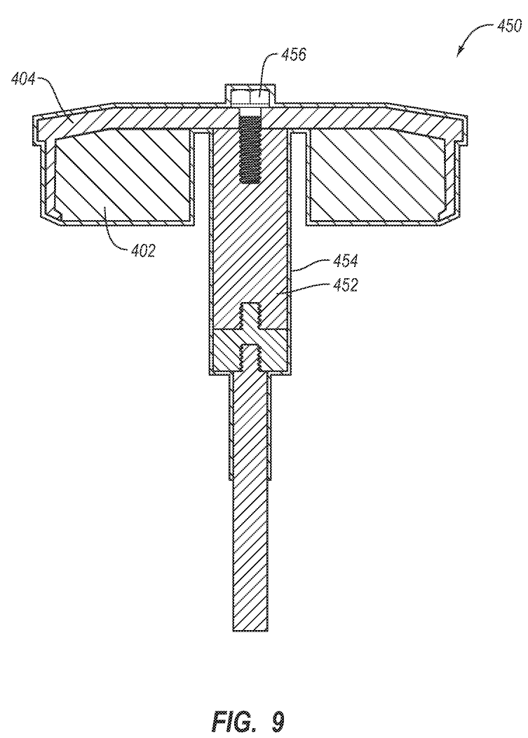

FIG. 6B shows an alternative embodiment of an x-ray focal track deposited on a carbon substrate. In this embodiment, a barrier layer 608 is positioned between substrate 602 and metal layer 612 (i.e., focal track 610). Barrier layer 608 is an optional layer that can be used to prevent the compounds in metal layer 612 from reacting with the carbon in substrate 602. A barrier layer under a target track material preferably has a thickness of less than about 20 microns, more preferably about 10 microns, and most preferably less than about 5 microns. Barrier layers are discussed more fully below with respect to FIGS. 8 and 9.

The x-ray target focal track can also be manufactured to cover only a portion of the carbon substrate, thereby leaving a portion of the carbon substrate exposed. FIG. 6C shows carbon substrate 602 with a barrier layer 608 and a metal layer 612, which provides an x-ray target focal track 610. Barrier layer 608 and metal layer 612 are not coated on portion 614 of substrate 602. Leaving portion 614 uncoated allows good heat dissipation from substrate 602. A portion 616 of barrier layer 608 is coated onto substrate 602 to reduce heat dissipation near the center of the substrate. This configuration of the barrier layer 608 and metal layer 612 can be achieved by grinding an intermediate target as in FIG. 6B to remove portions of barrier layer 608 and metal layer 612. Alternatively this configuration can be achieved by masking the portion 614 of substrate 602 during a first electroforming process to form barrier 608 and then masking both the portion 614 and portion 616 during a second electroforming process to form metal layer 612.

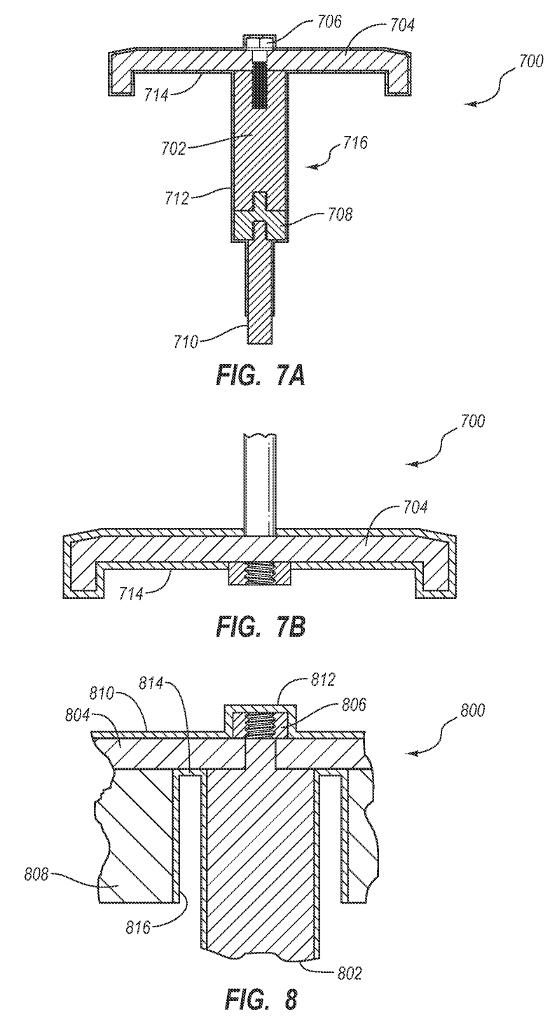

In an alternative embodiment, a target stem is manufactured using an electroforming process. FIG. 7A illustrates an intermediate target assembly 700 that has a target stem manufactured using an electroforming process. Intermediate target assembly 700 includes an electrically conductive stem core bolted to a metal x-ray target substrate 704 using fastener 706. A bearing support stud 708 is coupled to carbon stem core 702. Alternatively, stem core 702 can be a metal or metal alloy (e.g., a Mo alloy). An electroforming support member 710 is coupled to bearing support stud 708. An x-ray target stem sleeve 712 is formed on graphite core 702 and bearing stud 708 using electroforming apparatus 300 to form stem 716. The layer of metal that forms x-ray target stem sleeve 712 can extend beyond stem 716 to form layer 714 covering substrate 704. Layer 714 can be used as a barrier layer for a carbon substrate or an ODS Mo substrate and/or provide enhanced connection between stem 716 and substrate 704 to strengthen target 700.

FIG. 7A shows a solid-core stem 716. In an alternative embodiment, stem 716 can be a hollow stem. In one embodiment, stem 716 is made hollow by forming stem 712 around a graphite core and then removing the graphite core. To facilitate removing the graphite core, a graphite material can be used with a substantially different coefficient of thermal expansion as described above with respect to the method for manufacturing a substrate using a carbon block. Typically it is desirable to make the thickness of the stem greater for hollow stems as compared to stems that include a core material.

The electroforming process of the invention can be used to form metal layers on the substrate that function as a barrier layer or a metal layer used to strengthen and/or secure the components of the x-ray target assembly.

The barrier layers and strengthening metal layers can be electroformed independently or simultaneously with the electroformation of other layers of the x-ray target assembly. For example, in FIG. 6B, barrier layer 608 can be electroformed just prior to forming x-ray target focal track 610. FIG. 7A illustrates an embodiment where barrier layer 714 can be electroformed simultaneously with the electroformation of stem 712.

FIG. 7B illustrates an alternative embodiment for providing barrier layer 714 illustrated in FIG. 7A. In FIG. 7B, substrate 704 is coated with barrier layer 714 using electroforming apparatus 300 (FIG. 3). Barrier layer 714 can be formed on an ODS Mo substrate to prevent substrate 704 from forming gasses in a subsequent brazing step where a heat sink is bonded to substrate 704. By forming barrier layer 714 prior to forming a stem or focal track, the material used to make the barrier layer can be independent of the stem material and the focal track material. In an alternative embodiment, barrier layer can be electroformed on a carbon material to prevent the carbon material from reacting with other layers such as the target material. For example, a thin barrier layer of rhenium can prevent a tungsten layer from reacting with the carbon to form tungsten carbide, which has a lower melting point than tungsten and is more brittle.

The electroforming process can also be used to form layers that strengthen one or more components of the x-ray target assembly and/or secure two or more additional components of the x-ray target assembly. FIG. 8 is a cutaway view of an x-ray target assembly 800 showing a portion of a stem 802 coupled to a substrate 804 by a nut 806. Metal layer 810 is electroformed on substrate 804 and on nut 806 using electrodeposition (i.e., electroforming apparatus 300). Metal layer 810 secures nut 806 and stem 802 to substrate 804 and prevents nut 806 and stem 802 from rotating with respect to substrate 804. Securing nut 806 using electroformed layer 810 provides a significantly improved bond between nut 806 and substrate 802 as compared to using a braze washer to secure a stem assembly to a substrate. The electroformed layer 810 can be superior to a braze because electroformed layer 810 forms a better bond between the substrate 804 and nut 806 and stem 802. In addition, the selection of the metal for layer 810 is not constrained by melting point considerations like a braze would be. Consequently, pure metals and high melting point metals or metal alloys (e.g., tungsten or molybdenum) can be used to make layer 810 at a relatively low temperature (e.g., less than 1000° C.) without overheating other components of the intermediate target assembly.

FIG. 8 also illustrates a barrier layer 816 electroformed on one side of heat sink 808. Barrier layer 816 provides a thermal barrier to radiative heat dissipating from heat sink 808. This thermal barrier reduces heating of stem 802 and can increase the longevity of the x-ray target assembly and/or reduce thermal stress on stem 802. Barrier layer 816 is contiguous with strength enhancing layer 814 that bonds substrate 804 with heat sink 808 and stem 802. By making stem 802 and barrier layer 816 a continuous layer, stem 802, heat sink 808, and substrate 804 form a stronger assembly that is less prone to failure and/or poor performance due to high vibrations caused by an imbalance or week joints of target as compared to the same target assembly without layer 814.

In an alternative embodiment substrate 804 and heat sink 808 can be joined by brazing using a noble metal (e.g., platinum) rather than forming them using electrodeposition as described above with respect to FIG. 4B.

### IV. X-Ray Target Assemblies

The x-ray target components manufactured using an electroforming process are incorporated into an x-ray target assembly. The x-ray target assembly includes at least a substrate and a target material having a configuration and composition suitable for emitting x-rays when impinged upon by an electron source. In a preferred embodiment the x-ray target includes a substrate, an x-ray target focal track, and a stem.

The substrate can have any shape suitable for use in an x-ray tube. To facilitate rotation in a rotating anode target, the substrate is preferably disk-like. The thickness of the substrate and shape is selected to maximize strength, heat dissipation, and ease of manufacturing while minimizing cost. In one embodiment, the substrate is substantially disk shaped and has a thickness in a range from about 10 mm to about 14 mm.

The substrate can be made from any electrically conductive material. Because the x-ray target is used as an anode in the x-ray tube, the substrate should be electrically conductive to allow a charge to be applied to the target surface. The need to provide electrical conductivity when used in an x-ray tube is advantageous for making and/or coating the substrate using electroforming according to the invention since electroforming also requires electrically conductive surfaces.

The material used in the substrate can be carbon, carbon composites, metals, alloys, or oxide-dispersed-strengthened refractory metal (ODS refractory metal). In a preferred embodiment, the primary refractory metal is Mo. Molybdenum-based substrates have yielded exceptionally good substrates for use in rotating anode x-ray tubes.

Metal substrates can be manufactured using any combination of suitable techniques including powder metallurgy, machine grinding, extrusion, etc. If a carbon substrate is used, the carbon substrate is provided as a block of graphite, carbon composite, or other suitable conductive material. The carbon substrate can be machined to have desired features for an x-ray target assembly.

The x-ray target track material can be any material that can emit x-rays when impinged upon by an electron source. Examples of suitable materials include tungsten and alloys of tungsten, such as tungsten rhenium alloys. Preferably the track material is formed using an electroforming process as described above. Electroformed target focal tracks have surprisingly been found to be much more ductile than focal tracks made from the same material and manufactured using other technique such as powder metallurgy or vacuum plasma spay process. Due to the improved ductility, the electroformed target focal track can be manufactured using less rhenium, which traditionally has been added to improve ductility. In one embodiment, the percent of rhenium in a tungsten based focal track is less than 5 wt %, more preferably less than about 1 wt % and most preferably substantially free of rhenium. It is believed that the improved ductility is due to the substantially 100% dense columnar microcrystalline structure achieved in focal tracks manufactured using the electroforming process.

The x-ray target assembly typically includes a stem portion. The stem is a component used to support the target and, in the case of a rotating anode target, the stem is the means by which an induction rotor causes rotation of the x-ray target assembly. The stem typically includes the same metals that can be used as a metal substrate material.

A heat sink is typically used where the substrate is metallic. The heat sink is typically a carbon-based structure positioned on the substrate so as to absorb heat generated from electrons impinging upon the focal track and thereby creating x-rays. Where a carbon substrate is used, the carbon substrate can function as a heat sink and a heat sink is therefore not necessary.

If the x-ray target assembly includes a heat sink separate from the substrate, the heat sink can be made of any thermoconductive material such as, but not limited to, graphite or thermally conductive carbon composite. During use, the heat sink absorbs thermal energy from the substrate and dissipates the heat. The heat sink can have any shape or size so long as the heat sink adequately dissipates heat and is suitable for rotating anodes. Typically the heat sink is disk-shaped to facilitate high speed rotation. The surface of the heat sink that faces the substrate can have a regular or irregular pattern of grooves to enhance the surface area that bonds with the substrate. In one embodiment, the pattern comprises concentric or phonographic grooves.

The heat sink can be brazed or otherwise bonded to the substrate. Examples of suitable brazing materials include Zr, Ti, V, Cr, Fe, Co, Ni, Pt, Rd, or Pd or alloys including these elements. However, it can be advantageous to avoid a braze, since the braze can be a source of delamination. In one embodiment, the substrate is electroformed to the heat sink so as to avoid the necessity of brazing the heat sink to the substrate.

The x-ray target assembly optionally includes a barrier material. The barrier layer can be made from a substantially pure metal or an alloy. Examples of suitable metals include Mo, Ta, Re, W, Nb, V, Ir, Rh, Pt, and Pd, and combinations of these. These compounds can also be used in combination with boron, silicon, nitrogen, or carbon in the form of metal borides, nitrides, silicides, carbides, or combinations of these.

The thickness of the barrier layer can depend on the desired use of the barrier layer. If the barrier layer is to provide added strength, a relatively thicker layer is desired. Where the barrier layer is used to prevent a chemical reaction between to components of the x-ray target during electroforming or another manufacturing process, the barrier layer can be made only as thick as necessary to prevent the chemical reaction. In one embodiment, the barrier layer has a thickness in a range from about 0.01 mm to about 2.5 mm, more preferably in a range from about 0.1 mm to about 1.5 mm, and most preferably in a range from about 0.25 mm to about 1.0 mm.

Of the components used to manufacture the x-ray target assembly, any number of components can be manufactured using electroforming so long as the component can be made from a metal or metal alloy suitable for electrodeposition. While there are many advantages to using as many electroformed components as possible, embodiments of the invention contemplate as few as a single component manufactured using an electroforming process.

FIG. 9 illustrate an intermediate target assembly 450 incorporating target substrate 404 and heat sink 402 illustrated and described above with respect to FIG. 4B. Intermediate target assembly 450 includes a stem 452 manufactured according to the method illustrated and described above with respect to FIG. 7A. Intermediate target assembly 450 includes a metal layer 454 that coats stem 452 (thereby forming a stem sleeve), heat sink 402, substrate 404, and fastener 456.

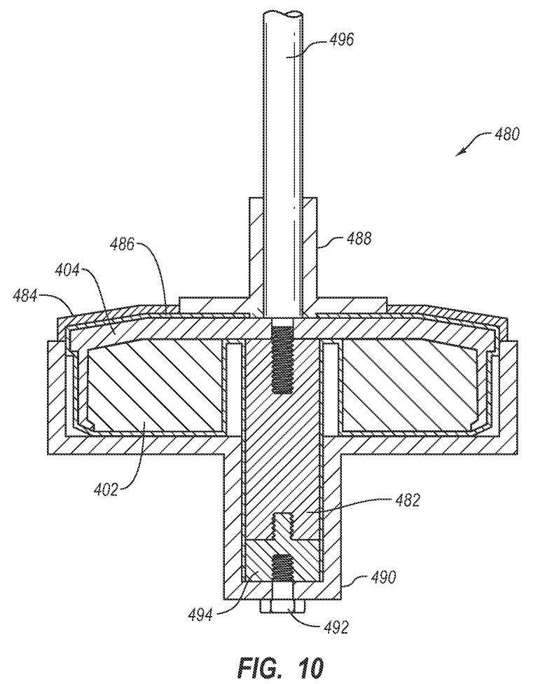

FIG. 10 illustrates an alternative embodiment of an x-ray target assembly 480 incorporating a focal track manufactured using an electroforming process according to the invention. Assembly 480 includes a substrate 404 and heat sink 402 as illustrated and described above with respect to FIG. 4B. Intermediate target assembly 480 includes a stem 482 manufactured according to the method illustrated and described above with respect to FIG. 7A. Stem 482 includes a bearing support stud 494. FIG. 10 further illustrates a focal track 484 formed on substrate 404 using electrodeposition. Barrier layer 486 separates focal track 484 from substrate 404. Focal track 484 is selectively deposited on substrate 404 by using masking 488 and 490. During electrodeposition, masking 490 is attached to stem 482 using a non-conductive nut 492. Masking 488 and 490 is a dielectric material such that the surface of masking 488 and 490 do not attract positively charged metal atoms in the electrolyte.

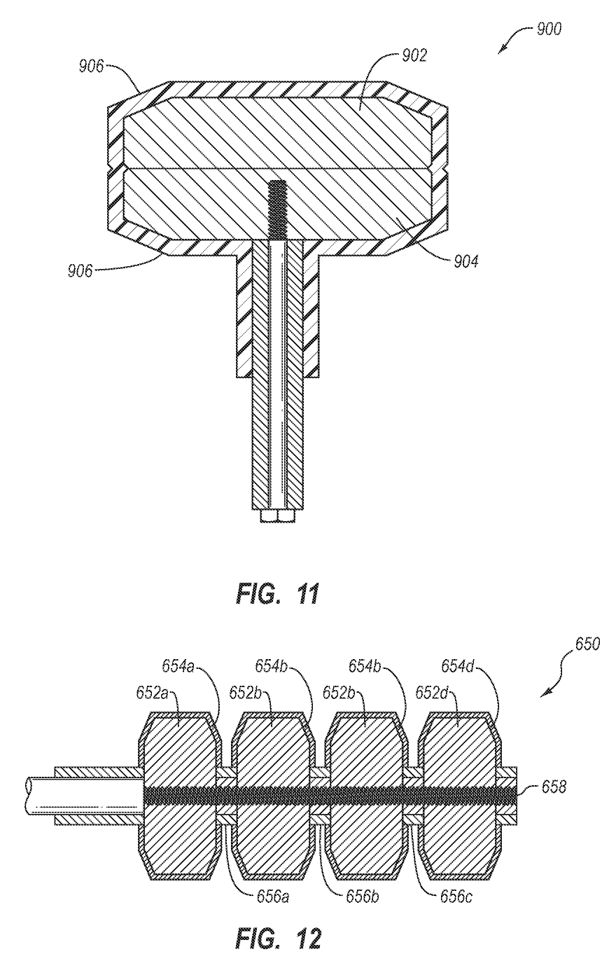

FIG. 11 illustrates an alternative embodiment of the invention where two or more targets are at least partially manufactured in a single electroforming process. Intermediate x-ray target 900 includes a first carbon block 902 and a second carbon block 904. Carbon blocks 902 and 904 have substantially identical dimensions. A substrate 906 is formed on carbon blocks 902 and 904 using an electroforming process (i.e., electroforming apparatus 300). The electroforming process deposits a substantially uniform layer of substrate material on carbon block 902 and carbon block 904. The two carbon blocks are separated from each other and the substrates on respective blocks 902 and 904 are machined to have a configuration substantially similar to that of the substrate and heat sink described in FIG. 4B.

FIG. 12 illustrates yet another alternative embodiment of the invention. FIG. 12 shows a multi target assembly 650. Multi target assembly 650 includes, for example, four targets 652a-652d manufactured using the method described above with respect to FIG. 6A. However, multi-target assembly 650 can include any number of targets. Targets 652a-652d include a focal track 654a-654d, respectively. Focal tracks 654 are manufactured using electroforming as described above. Targets 652 are separated using ceramic spacers 656a-656c, or alternatively sacrificial spacers made from a conductive material such as graphite. Fastener 658 couples targets 652 together. In a preferred embodiment, focal tracks 654 are formed in the same electrodeposition process to ensure a more uniform deposition of focal tracks 654 on respective targets 652.

### V. Use of Target Assembly in X-Ray Tube and CT-Scanner

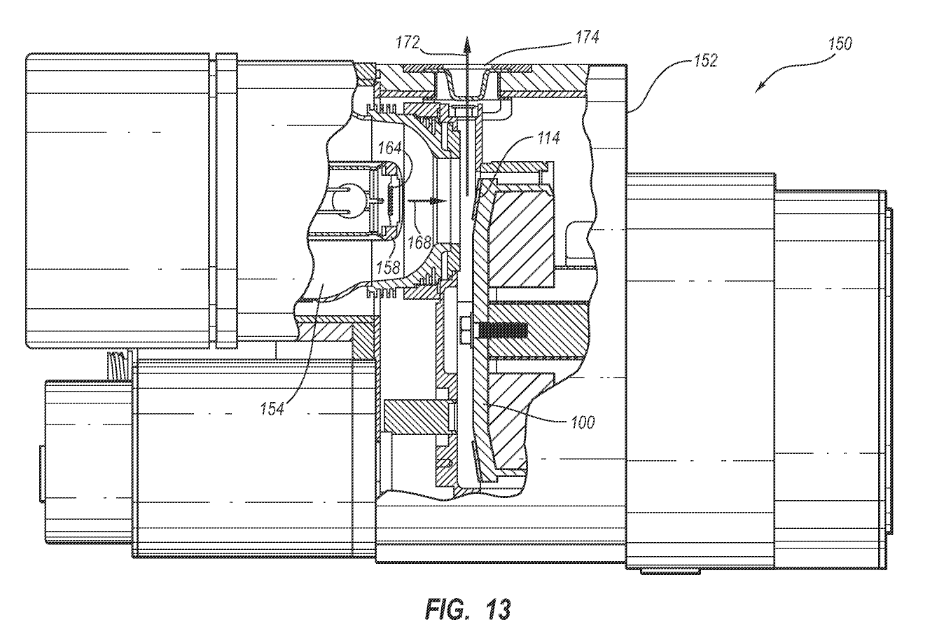

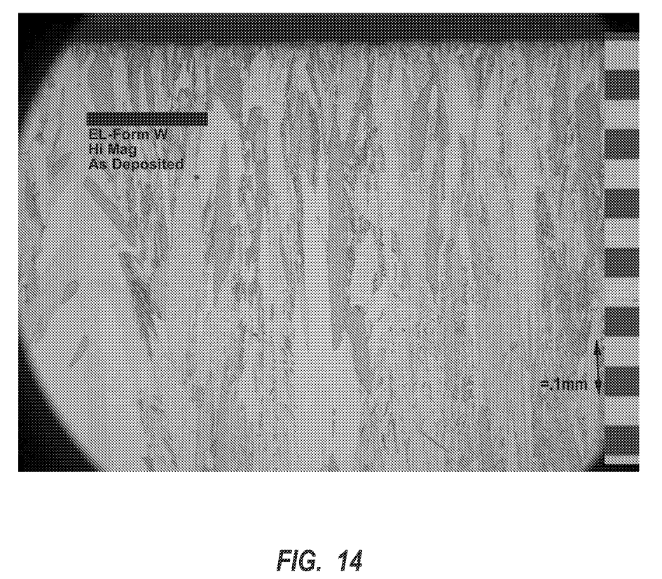

The x-ray target assemblies of the present invention can advantageously be incorporated into an x-ray tube. FIG. 13 illustrates an x-ray tube 150 that includes an outer housing 152, within which is disposed in an evacuated enclosure 154. Disposed within evacuated enclosure 154 is a cathode 158 and a rotating anode x-ray target assembly 100, manufactured according to the present invention. Assembly 100 is spaced apart from and oppositely disposed to cathode 158.

As is typical, a high-voltage potential is provided between assembly 100 and cathode 158. In the illustrated embodiment, cathode 158 is biased by a power source (not shown) to have a large negative voltage, while assembly 100 is maintained at ground potential. In other embodiments, the cathode is biased with a high negative voltage while the anode is biased with a high positive voltage. Cathode 158 includes at least one filament 164 that is electrically connected to a power source. During operation, electrical current is passed through the filament 164 to cause electrons, designated at 168, to be emitted from cathode 158 by thermionic emission. Application of the high-voltage differential between anode assembly 100 and cathode 158 then causes electrons 168 to accelerate from cathode filament 164 toward a focal track 114 that is positioned on a target surface of rotating assembly 100.

As electrons 168 accelerate, they gain a substantial amount of kinetic energy, and upon striking the target material on focal track 114, some of this kinetic energy is converted into electromagnetic waves of very high frequency (i.e., x-rays). At least some of the emitted x-rays, designated at 172, are directed through x-ray transmissive window 174 disposed in outer housing 152. Window 174 is comprised of an x-ray transmissive material so as to enable the x-rays to pass through window 174 and exit x-ray tube 150. The x-rays exiting tube 150 can then be directed for penetration into an object, such as a patient's body during a medical evaluation, or a sample for purposes of metals and chemical analysis and baggage inspection.

The high performance and/or larger diameters of the x-ray target assemblies of the present invention make the x-ray target assemblies of the invention particularly suitable for use in high performance devices such as CT-scanners. CT-scanners incorporating the x-ray tubes of the invention can achieve higher intensity x-rays that allow for higher resolution medical imaging and baggage inspection. Thus, the CT-scanners of the invention can be made to detect medical or material features that might not otherwise be possible with x-ray tubes having inferior performance.

The disclosed embodiments are to be considered in all respects only as exemplary and not restrictive. The scope of the invention is, therefore, indicated by the appended claims rather than by the foregoing disclosure. All changes which come within the meaning and range of equivalency of the claims are to be embraced within their scope.

What is claimed is:

1. A method for manufacturing an x-ray target assembly using an electroforming process, comprising:
providing an electroforming apparatus, an electrolyte, a metal anode, and an electrically conductive cathode, wherein the cathode comprises (i) an intermediate x-ray target assembly, (ii) an electrically conductive mold for forming a component of an x-ray target assembly, or (iii) both (i) and (ii);
forming at least one metal component of an x-ray target assembly by electrodeposition of at least a portion of the metal from the anode onto the electrically conductive cathode; and
incorporating the at least one metal component into an assembly so as to yield the x-ray target assembly.

2. A method as in claim 1, wherein the at least one metal component that is formed by the electrodeposition is an x-ray target substrate, an x-ray target focal track, an x-ray target stem, a metal barrier layer on a metal x-ray target substrate, a metal barrier layer on a carbon x-ray target substrate, a metal barrier layer on a carbon x-ray target heat sink, or a metal layer that mechanically couples two or more additional components of the x-ray target assembly.

3. A method as in claim 1, wherein the metal anode of the electroforming apparatus comprises one or more metals selected from the group consisting of Mo, Ta, Re, W, Nb, V, Ir, Rh, Pt, and Pd.

4. A method as in claim 1, wherein the metal anode comprises two or more metals and the metal component of the target assembly that is formed by the electrodeposition comprises a metal alloy.

5. A method as in claim 4, wherein the metal alloy is graded.

6. A method as in claim 1, wherein the electrolyte is a molten salt.

7. A method as in claim 1, wherein the electrodeposition is carried out at a temperature greater than about 500° C.

8. A method as in claim 1, wherein the rate of electrodeposition is in a range from 5 microns/hour to about 80 microns/hour.

9. A method as in claim 1, wherein the electrically conductive cathode comprises a target substrate, wherein the substrate is graphite or a refractory metal.

10. A method as in claim 1, wherein the x-ray target assembly includes an x-ray target stem connected to an x-ray target substrate with a fastener, wherein the electroformed component is a metal layer that bonds the fastener to the substrate.

11. A method as in claim 1, wherein the cathode comprises two or more target substrates and at least one metal component of an x-ray target assembly is formed on each target substrate in a single electrodeposition step.

12. An x-ray target assembly manufactured according to the method of claim 1, thereby yielding an x-ray target assembly with a metal component having a substantially columnar microcrystalline structure and substantially 100% density.

13. An x-ray target assembly as in claim 11, wherein the metal component formed by the electrodeposition has a thickness of at least 1.0 mm.

14. A method for manufacturing an x-ray target assembly, comprising:
providing an electroforming apparatus, an electrolyte, a metal anode, and an electrically conductive cathode, wherein the electrically conductive cathode comprises an x-ray target substrate; and
electrodepositing a metal on the substrate to form an x-ray target focal track.

15. A method as in claim 13, wherein a metal layer is formed between the substrate and the x-ray target focal track using an electroforming process.

16. A method as in claim 13, further comprising forming a stem sleeve on the substrate by depositing a metal using an electroforming process.

17. A method as in claim 15, wherein (i) the stem sleeve is formed around a graphite core, wherein the graphite core is removed after the sleeve is formed by the electroforming process or (ii) wherein the stem sleeve is formed around a stem core that is connected to the substrate using a fastener.

18. A method as in claim 15, wherein the target comprises an alloy in which the concentration of at least one alloying element is graded through at least a portion of the depth of the track.

19. A method as in claim 15, wherein the track comprises tungsten and rhenium, and wherein the rhenium is graded through at least a portion of the depth of the track.

20. An x-ray target assembly manufactured according to the method of claim 15, thereby yielding an anode target with a focal track having a substantially columnar microcrystalline structure and substantially 100% density.

21. A method for manufacturing an x-ray target assembly, comprising:
providing an electroforming apparatus, an electrolyte, a metal anode, and an electrically conductive cathode;
electrodepositing a metal on the cathode to form an x-ray target substrate; and
forming an x-ray target track on the substrate.

22. A method as in claim 21, wherein the substrate has a substantially uniform thickness under the focal track.

23. A method as in claim 21, wherein the substrate is formed on a carbon block, the carbon block being shaped to form a heat sink, wherein the heat sink is on the underside of the substrate and the focal track is formed on the upper side of the substrate, the substrate having a skirt portion that extends around at least a portion of the lateral edge of the carbon heat sink.

24. An rotating x-ray target assembly, comprising:
an x-ray target substrate;
a target stem coupled to the substrate so as to allow the substrate to be rotated by rotating the stem;
an x-ray target focal track deposited on an upper side of the x-ray target substrate;
a carbon heat sink bonded to the substrate on a side opposite the focal track, the heat sink having a lateral edge, wherein a portion of the substrate covers at least about 50% of the lateral edge of the heat sink to prevent carbon from fracturing during rotation.

25. An x-ray target assembly as in claim 24, wherein the portion of the substrate directly below the focal track has a substantially uniform thickness.
